(19) United States
(12) Patent Application Publication
(10) Pub. No.: US 2015/0228697 A1
(43) Pub. Date: Aug. 13, 2015

(54) ORGANIC LIGHT EMITTING DIODE (OLED) DEVICE AND A METHOD OF FABRICATING THE SAME

(71) Applicant: SHENZHEN CHINA STAR OPTOELECTRONICS TECHNOLOGY CO., LTD., Shenzhen, Guangdong (CN)

(72) Inventors: Yawei Liu, Shenzhen City (CN); Yifan Wang, Shenzhen City (CN)

(21) Appl. No.: 14/124,715

(22) PCT Filed: Sep. 30, 2013
(86) PCT No.: PCT/CN13/84660

§ 371 Date: Dec. 8, 2013

(30) Foreign Application Priority Data
Sep. 12, 2013 (CN) 201310416409.7

(51) Int. Cl. H01L 27/32; H01L 51/50; H01L 51/56; H01L 51/52

(52) U.S. Cl. CPC H01L 27/322; H01L 51/524; H01L 51/5262; H01L 51/5036; H01L 51/5253; H01L 51/5088; H01L 51/5056; H01L 51/5072; H01L 51/5206; H01L 51/5221; H01L 51/5012; H01L 51/56; H01L 27/3244; H01L 51/005

(57) ABSTRACT

The present invention provides a color OLED device and method of fabricating the same. The color OLED device includes an OLED substrate, an OLED cover adhered to the OLED substrate and a color conversion layer formed on the OLED cover. The OLED substrate includes an OLED element formed thereon, and the OLED element includes a light emitting layer. The color conversion layer includes a plurality of quantum dots, light emitting from the light emitting layer is converted to colored light with the plurality of quantum dots in the color conversion layer. According to present invention, a color OLED device can be colorized with the plurality of quantum dots in the color conversion layer; moreover, with the characteristics of the plurality of quantum dots, a thickness of the color OLED device including the light emitting layer can be shrunken, lifetime, and color purity thereof can be enhanced.

### FIELD OF THE INVENTION

The present invention relates to an OLED device and a method of fabricating the same, more particularly to a color OLED device and a method of fabricating the same.

### BACKGROUND OF THE INVENTION

There are several ways of fabricating a color organic light emitting diode (OLED) device. One way led by Samsung Electronics Co., Ltd. is RGB OLEDs technique. The RGB OLEDs technique is only applicable to small organic molecules which are easily sublimated, and has mature and easy fabricating processes. However, as a need of high-precision mask and precise alignment (i.e. lithography) in fabricating high-resolution OLED displays, the RGB OLEDs technique results in lower production and higher cost; moreover, highly differential characteristics such as lifetime, luminescence rate and attenuation between red, green and blue OLEDs cause color cast resulting in color OLED displays.

Another way led by LG Corporation is white OLEDs plus RGB color filter (WOLED&RGBCF) technique. The WOLED&RGBCF technique can greatly simplify deposition processes as mature CF technology in LCD art applied thereto and high-precision lithography omitted therein, thus, the WOLED&RGBCF technique reduces production costs, so that the WOLED&RGBCF technique is generally used to fabricate large-size high-resolution OLED. However, due to the color filter in the WOLED&RGBCF devices absorbing most of light emitting from white OLEDs, only about 30% light emitting from the white OLEDs can transmit the color filter. Therefore, the white OLEDs having high luminescence rate shall be needed, otherwise the WOLED&RGBCF devices have poor efficiency. The WOLED&RGBCF technique is generally used for OLED display of small organic light emitting molecules.

To obviate drawbacks of the above said ways of fabricating a color OLED device, a color conversion technique (called color by blue (CBB) technique) has been developed by Idemitsu Kosan Co., Ltd. and Fuji Electric Co., Ltd. The CBB technique colorizes a OLED device by converting blue light emitting from blue OLEDs to red and green light with a color conversion method (called CCM). The CBB technique can be performed with the mature CF technology, and have high pixel density and production in comparison to RGB OLEDs technique.

To achieve RGB light, the CBB technique allows blue light respectively transmitting materials capable of converting the blue light to red and green light, and the mechanism of the CBB technique includes photoluminescence and electroluminescence. Due to lithography not needed in the CCM, deposition processes therein can be simplified, and large-size OLED displays can be fabricated with the CCM. A key point of the CBB technique is restricted to blue light materials, so that the CBB technique is generally used for OLED display of small organic light emitting molecules at the present stage. Generally, a conventional light color conversion material for use in the CBB technique is a blend solution of organic fluorescent dye and photoresist polymer; however, a conversion rate of the conventional light color conversion material is low, because unsaturated bonds in the photoresist polymer and light-induced reaction agents reacted with the fluorescent dye results in a concentration quenching.

Inorganic quantum dots having a plurality of advantages such as high photoluminescence, excellent stability, long lifetime, broader absorption spectral width and color purity, etc. have been widely used in biological and medical diagnostic fluorescent probe, a material including the inorganic quantum dots shall be an excellent photoluminescence material for using as OLED color conversion layer material. However, this aspect has not been reported.

### SUMMARY OF THE INVENTION

In accordance with an aspect, the present invention provides a color OLED device which can be fabricated with simplified fabrication processes, and has high color purity, excellent stability and long lifetime.

In accordance with another aspect, the present invention provides a method of fabricating a color OLED device having high color purity, excellent stability and long lifetime.

For the aspect, the present invention provides a color OLED device including an OLED substrate, an OLED cover adhered to the OLED substrate and a color conversion layer formed on the OLED cover, wherein the OLED substrate has an OLED element formed thereon, the OLED element includes a light emitting layer, the color conversion layer includes a plurality of quantum dots, and light emitting from the light emitting layer is converted to colorized light with the plurality of quantum dots.

In an embodiment, the light emitting layer is a blue light emitting layer, the color conversion layer includes green quantum dots, red quantum dots and blank units disposed in intervals, wherein blue light emitting from the light emitting layer is respectively converted to green light with the green quantum dots, red light with the red quantum dots and still the blue light with the blank units in transmitting the color conversion layer.

In an embodiment, the light emitting layer includes a blue light emitting material formed by thermal evaporation of polyfluorene, 4,4′-bis(2,2-diphenyl vinyl)biphenyl or bis(2,4-difluorophenyl pyridyl)-tetra(1-pyrazolyl)borate iridium.

In an embodiment, the light emitting layer further includes a host organic blue light material layer formed by thermal evaporation of 4,4′,4″-tris(carbazol-9-yl)triphenylamine or 2,4,6-(9H-carbazol-9-yl)-1,3,5-triazine.

In an embodiment, the green quantum dots are formed with cadmium selenide, zinc sulfide or zinc selenide doped with copper ions; and the red quantum dots are formed with cadmium selenide, cadmium sulfide or zinc sulfide.

In an embodiment, the light emitting layer is a white light emitting layer, the color conversion layer includes green quantum dots, red quantum dots and blue quantum dots disposed in intervals, wherein white light emitting from the light emitting layer is respectively converted to green light with the green quantum dots, red light with the red quantum dots and blue light with the blue quantum dots in transmitting the color conversion layer.

In an embodiment, the light emitting layer is a white light emitting layer, the color conversion layer includes green quantum dots, red quantum dots, blue quantum dots and white light transmission units disposed in intervals, wherein white light emitting from the light emitting layer is respectively converted to green light with the green quantum dots, red light with the red quantum dots, blue light with the blue quantum dots and still the white light with the white light transmission units in transmitting the color conversion layer.

In an embodiment, the color OLED device further includes a protection layer formed on the color conversion layer, and the protection layer is formed with stearic acid, zinc oxide phosphine, or polymethylmethacrylate.

In an embodiment, the OLED element includes an anode formed on the OLED substrate, a thin film transistor (TFT) array formed on the anode, a hole injection layer formed on the TFT array, a hole transport layer formed on the hole injection layer, an electron transport layer formed above the hole transport layer, and a cathode formed on the electron transport layer, wherein the light emitting layer is formed between the hole transport layer and electron transport layer, the hole injection layer is formed with polyethylene dioxythiophene, the hole transport layer is formed with polytriphenylamine, and the electron transport layer is formed with aluminum 8-hydroxyquinoline.

For another aspect, the present invention provides a color OLED device including an OLED substrate, an OLED cover adhered to the OLED substrate and a color conversion layer formed on the OLED cover, wherein the OLED substrate has an OLED element formed thereon, the OLED element includes a light emitting layer, the color conversion layer includes a plurality of quantum dots, and light emitting from the light emitting layer is converted to colorized light with the plurality of quantum dots;

the light emitting layer is a blue light emitting layer, the color conversion layer includes green quantum dots, red quantum dots and blank units disposed in intervals, blue light emitting from the light emitting layer is respectively converted to green light with the green quantum dots, red light with the red quantum dots and still the blue light with the blank units in transmitting the color conversion layer;
the light emitting layer includes a blue light emitting material formed by thermal evaporation of polyfluorene, 4,4′-bis(2,2-diphenyl vinyl)biphenyl or bis(2,4-difluorophenyl pyridyl)-tetra(1-pyrazolyl)borate iridium; and the light emitting layer further includes a host organic blue light material layer formed by thermal evaporation of 4,4′,4″-tris(carbazol-9-yl)triphenylamine or 2,4,6-(9H-carbazol-9-yl)-1,3,5-triazine.

In an embodiment, the color OLED further includes a protection layer formed on the color conversion layer, and the protection layer is formed with stearic acid, zinc oxide phosphine, or polymethylmethacrylate.

In an embodiment, the OLED element includes an anode formed on the OLED substrate, a thin film transistor (TFT) array formed on the anode, a hole injection layer formed on the TFT array, a hole transport layer formed on the hole injection layer, an electron transport layer formed above the hole transport layer, and a cathode formed on the electron transport layer, wherein the light emitting layer is formed between the hole transport layer and electron transport layer, the hole injection layer is formed with polyethylene dioxythiophene, the hole transport layer is formed with polytriphenylamine, and the electron transport layer is formed with aluminum 8-hydroxyquinoline.

In an embodiment, the green quantum dots are formed with cadmium selenide, zinc sulfide or zinc selenide doped with copper ions; and the red quantum dots are formed with cadmium selenide, cadmium sulfide or zinc sulfide.

For another aspect, the present invention provides a method of fabricating a color OLED device including steps as follows:

step 1, providing an OLED substrate;

step 2, forming an anode on the OLED substrate;

step 3, forming a thin film transistor (TFT) array on the anode;

step 4, sequentially forming a hole injection layer and a hole transport layer on the TFT array;

step 5, forming a light emitting layer on the hole transport layer, wherein the light emitting layer is a blue light emitting layer or a white light emitting layer;

step 6, sequentially forming an electron transport layer and a cathode on the light emitting layer;

step 7, providing an OLED cover, and adhering the OLED cover to the OLED substrate with a sealant;

step 8, forming a color conversion layer on the OLED cover, and forming a protection layer on the color conversion layer so that the color OLED device is formed, wherein the color conversion layer includes a plurality of quantum dots, and light emitting from the light emitting layer is converted to colorized light with the plurality of quantum dots;

in case of the light emitting layer being the blue light emitting layer, the color conversion layer includes green quantum dots, red quantum dots and blank units disposed in intervals, wherein blue light emitting from the light emitting layer is respectively converted to green light with the green quantum dots, red light with the red quantum dots and still the blue light with the blank units in transmitting the color conversion layer; and

in case of the light emitting layer being the white light emitting layer, the color conversion layer includes green quantum dots, red quantum dots and blue quantum dots disposed in intervals, wherein white light emitting from the light emitting layer is respectively converted to green light with the green quantum dots, red light with the red quantum dots and blue light with the blue quantum dots in transmitting the color conversion layer.

A color OLED device according to the present invention is colorized with the light emitting layer and the plurality of quantum dots, a thickness of the light emitting layer can be shrunken, thus a thickness of the color OLED device can be shrunken; moreover, due to the characteristics of the plurality of quantum dots such as excellent stability, long lifetime, broader absorption spectral width and color purity, thus a lifetime and color purity of the color OLED device can be enhanced; additionally, a method of fabricating a color OLED device according to the present invention has simplified fabrication processes, thus a fabrication cost of the method thereof can be easily reduced.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating a color OLED device according to a first embodiment of the present invention;

FIG. 2 is a schematic top view illustrating a driving circuit of a pixel in the color OLED device according to the first embodiment of the present invention as shown in FIG. 1;

FIG. 3 is a schematic top view illustrating an arrangement of sub-pixels of pixels in the color OLED device according to the first embodiment of the present invention as shown in FIG. 1;

FIG. 4 is a schematic top view illustrating another arrangement of sub-pixels of pixels in the color OLED device according to the first embodiment of the present invention as shown in FIG. 1;

FIG. 5 is a schematic cross-sectional view illustrating a color OLED device according to a second embodiment of the present invention;

FIG. 6 is a schematic top view illustrating an arrangement of sub-pixels of pixels in the color OLED device according to the second embodiment of the present invention;

FIG. 7 is a schematic cross-sectional view illustrating a color OLED device according to a third embodiment of the present invention;

FIG. 8 is a schematic top view illustrating an arrangement of sub-pixels of pixels in the color OLED device according to the third embodiment of the present invention;

FIG. 9 is a schematic top view illustrating another arrangement of a sub-pixels of pixel in the color OLED device according to the third embodiment of the present invention; and

FIG. 10 is a flow chart illustrating a method of fabricating a color OLED device according to the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

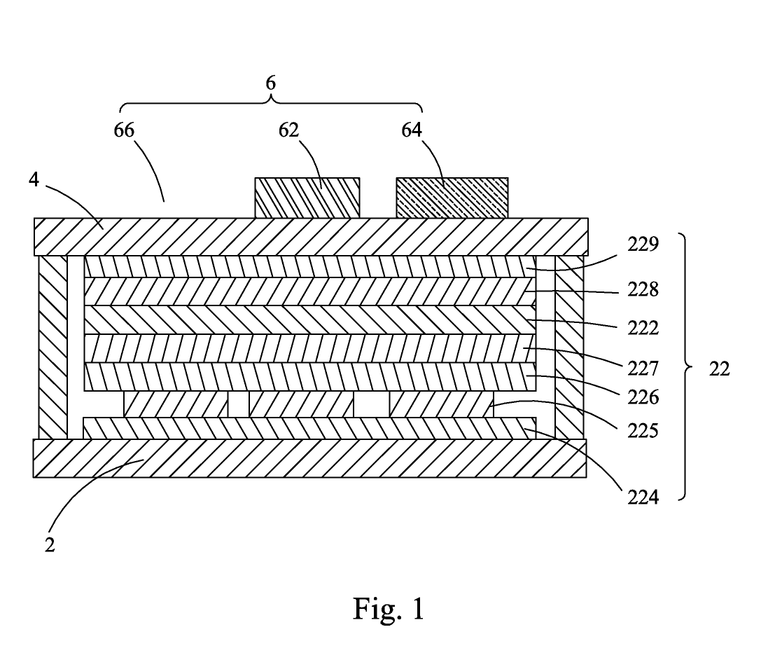

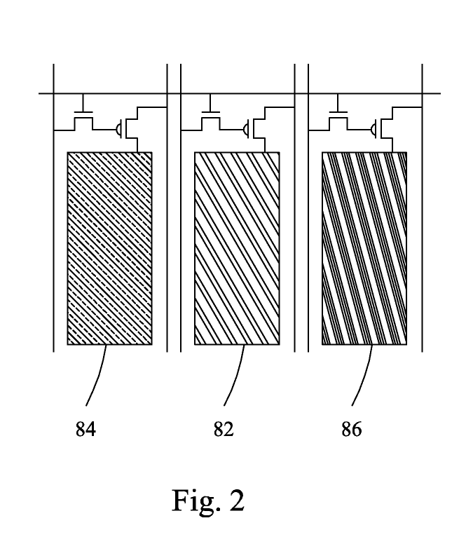

FIG. 1 is a schematic cross-sectional view illustrating a color OLED device according to a first embodiment of the present invention; and FIG. 2 is a schematic top view illustrating a driving circuit of a pixel in the color OLED device according to the first embodiment of the present invention as shown in FIG. 1. Please refer to FIGS. 1 and 2, the present invention provides a color OLED device including an OLED substrate 2, an OLED cover 4 adhered to the OLED substrate 2 and a color conversion layer 6 formed on the OLED cover 4, wherein the OLED substrate 2 has an OLED element 22 formed thereon, the color conversion layer 6 includes a plurality of quantum dots, light emitting from the OLED element 22 is converted to colorized light with the plurality of quantum dots; the color OLED device according to the present invention can be fabricated with simplified fabrication processes, and has high color purity, excellent stability and long lifetime. In the color OLED device, at least one of the OLED substrate 2 and the OLED cover 6 is fabricated with transparent material; in this preferred embodiment, both the OLED substrate 2 and the OLED cover 6 are fabricated with glass substrates. The OLED cover 6 is adhered to the OLED substrate 2 with a sealant to prevent the OLED element 22 from external moisture causing corrosion of the OLED element 22, so as to guarantee lifetime of the color OLED device.

The OLED element 22 includes an anode 224 formed on the OLED substrate 2, a thin film transistor (TFT) array 225 formed on the anode 224, a hole injection layer (HIL) 226 formed on the TFT array 225, a hole transport layer (HTL) 227 formed on the hole injection layer 226, the light emitting layer 222 formed on the hole transport layer 227, an electron transport layer (ETL) 228 formed on the light emitting layer 227, and a cathode 229 formed on the electron transport layer 228, wherein the light emitting layer 222 is formed between the hole transport layer 227 and electron transport layer 228.

In this embodiment, the hole injection layer 226 is formed by thermal evaporation of polyethylene dioxythiophene (PEDOT), the hole transport layer 227 is formed by thermal evaporation of polytriphenylamine (poly-TPD), and the electron transport layer is formed by thermal evaporation of aluminum 8-hydroxyquinoline (Alq₃).

Further, in this embodiment, the light emitting layer 222 is a blue light emitting layer, the color conversion layer 6 includes green quantum dots 62, red quantum dots 64 and blank units 66 disposed in intervals, wherein blue light emitting from the light emitting layer 222 is respectively converted to green light with the green quantum dots 62, red light with the red quantum dots 64 and still the blue light with the blank units 66 in transmitting the color conversion layer 6, so as the light emitting form the light emitting layer 222 is colorized.

Specifically, each group of the green quantum dot 62, red quantum dot 64 and blank unit 66 is corresponding to a pixel of the color OLED device; in this embodiment, the green quantum dot 62 is corresponding to a green sub-pixel 82 of the pixel, the red quantum dot 64 is corresponding to a red sub-pixel 84 of the pixel, and the blank unit 66 is corresponding to a blue sub-pixel 86 of the pixel.

In this embodiment, the green quantum dots 62 are formed with cadmium selenide (CdSe), zinc sulfide (ZnS) or zinc selenide doped with copper ions (ZnSe:Cu²⁺); the red quantum dots 64 are formed with cadmium selenide (CdS), cadmium sulfide or zinc sulfide; and the blank units 66 are not identical to the green quantum dots 62 or the red quantum dots which are formed with specific material. A specific way of fabricating the blank units 66 includes steps as follows. Firstly, the red quantum dots 64 corresponding to the red sub-pixel 84 of pixels are formed on the OLED cover 4. Then, the green quantum dots 62 corresponding to the green sub-pixel 82 of pixels are formed on the OLED cover 4. Then, locations above the OLED cover 4 corresponding to blue sub-pixel 86 of pixels are retained, and defined as blank units 66 herein.

Specifically, the light emitting layer 222 includes a blue light emitting material formed by thermal evaporation of polyfluorene, 4,4′-bis(2,2-diphenyl vinyl)biphenyl (DPVBi) or bis(2,4-difluorophenyl pyridyl)-tetra(1-pyrazolyl)borate iridium.

Further, the light emitting layer 222 includes a host organic blue light material layer formed by thermal evaporation of 4,4′,4″-tris(carbazol-9-yl)triphenylamine (TCTA) or 2,4,6-(9H-carbazol-9-yl)-1,3,5-triazine (TRZ). TCTA has a structural formula

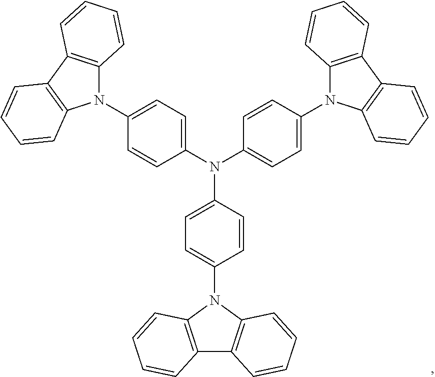 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

as and 2,4,6-(9H-carbazol-9-yl)-1,3,5-triazine has a structural formula as

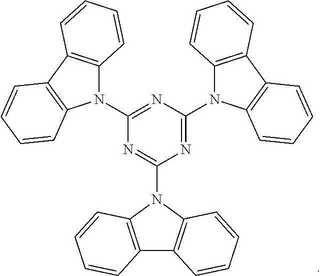 [SMILES: c1ccc2c(c1)c1ccccc1n2-c1nc(-n2c3ccccc3c3ccccc32)nc(-n2c3ccccc3c3ccccc32)n1]

It is noted that the color OLED device can further include a protection layer (not shown) formed on the color conversion layer 6, and the protection layer as a transparent protection layer can be formed with stearic acid, zinc oxide phosphine, or polymethylmethacrylate. In practice, a solution of stearic acid, zinc oxide phosphine, or polymethylmethacrylate is formed with a solvent; then, the solution thereof is coated over the green quantum dots 62 and the red quantum dots 64; and the protection layer is formed after the solvent has been vaporized. Due to the plurality of quantum dots being nanoparticle, zero-dimensional material, surface-active, and prone to agglomerate resulting in oxidation and fluorescence quenching, the protection layer can prevent the plurality of quantum dots from resulting in oxidation and fluorescence quenching

Please refer to FIG. 2, in this embodiment, each pixel disposed in the color OLED device includes three sub-pixels, and each sub-pixel is corresponding to a thin film transistor (TFT), the TFT controls luminescence of a region of the blue light emitting layer corresponding to each sub-pixel. Each group of the green quantum dot 62, red quantum dot 64 and blank unit 66 is respectively corresponding to three sub-pixels of each pixel, when the TFT corresponding to the green sub-pixel allows luminescence of a region of the blue light emitting layer, blue light emitting from the light emitting layer is converted to green light in transmitting the green quantum dot 62 in the color conversion layer 6; similarly, when the TFT corresponding to the red sub-pixel allows luminescence of a region of the blue light emitting layer, blue light emitting from the light emitting layer is converted to red light in transmitting the red quantum dot 64 in the color conversion layer 6; and when the TFT corresponding to the blue sub-pixel allows luminescence of a region of the blue light emitting layer, blue light emitting from the light emitting layer is still the blue light in transmitting the blank unit 66 in the color conversion layer 6, so that the blue light emitting from the blue light emitting layer can be colorized with the color conversion layer 6 according to the present invention.

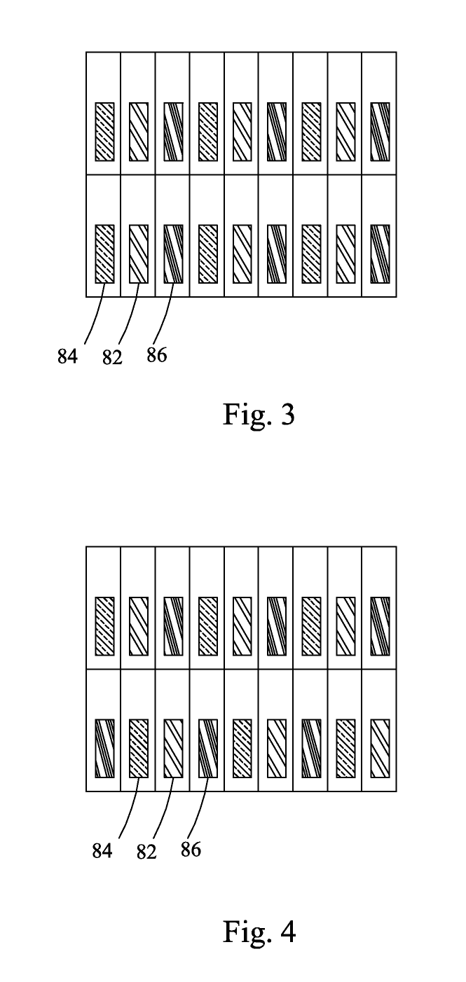

The three sub-pixels of the pixel in adjacent two rows (upper and lower lines) can be arranged in same or different arrangement, and the arrangement of the sub-pixels has no limit to performance of the color OLED device according to the present invention. In the first embodiment of the present invention specifically shown in FIG. 3, an arrangement from left to right of the sub-pixels of the pixel in the adjacent two rows is same as the red, green and blue sub-pixels 84, 82 and 86. On contrast, as shown in FIG. 4, another arrangement from left to right of the sub-pixels of the pixel in adjacent two rows is that the red, green and blue sub-pixels 84, 82 and 86 arranged in the upper line of the adjacent two rows, and the blue, red and green sub-pixels arranged in the lower line thereof; i.e., the red sub-pixel 84 in the upper line of the adjacent two rows is corresponding to the blue sub-pixel 86 in the lower line thereof, the green sub-pixel 82 in the upper line thereof is corresponding to the red sub-pixel 84 in the lower line thereof, and the blue sub-pixel 86 in the upper line thereof is corresponding to the lower line thereof. It is noted that the above description interpret the arrangements such as shown in FIG. 3 and FIG. 4 having no effect on performance of the color OLED device according to the present invention; moreover, it represents that the subject matter recited in the present invention can be applied to color OLED devices having different arrangements of sub-pixels arranged therein, and allow the color OLED devices have excellent performance such as long lifetime, high color purity.

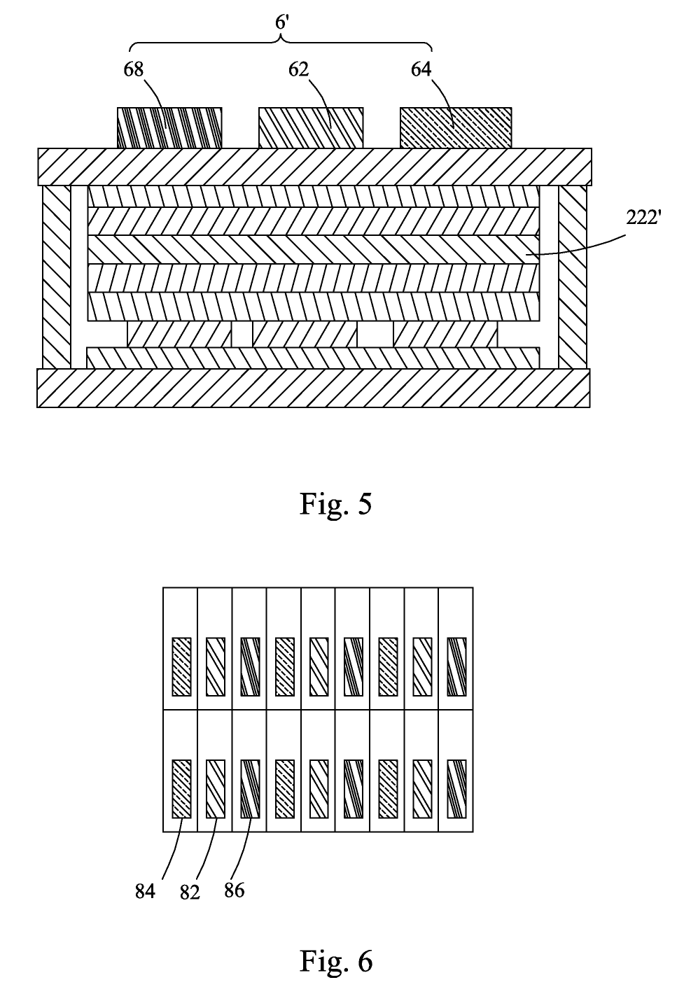

FIG. 5 is a schematic cross-sectional view illustrating a color OLED device according to a second embodiment of the present invention. Please refer to FIG. 5, in this embodiment, the light emitting layer 222′ is a white light emitting layer, the color conversion layer 6′ includes the green quantum dots 62, the red quantum dots 64 and the blue quantum dots 68 disposed in intervals, wherein white light emitting from the light emitting layer 222′ is converted to green light with the green quantum dots 62 in the color conversion layer 6′, white light emitting from the light emitting layer 222′ is converted to red light with the red quantum dots 64 in the color conversion layer 6′, and white light emitting from the light emitting layer 222′ is converted to blue light with the blue quantum dots 68 in the color conversion layer 6′. Please refer to FIG. 6, an arrangement of sub-pixels of pixels disposed in the color OLED device according to the second embodiment of the present invention can be the same as the arrangement of the first embodiment as shown in FIG. 3 or FIG. 4.

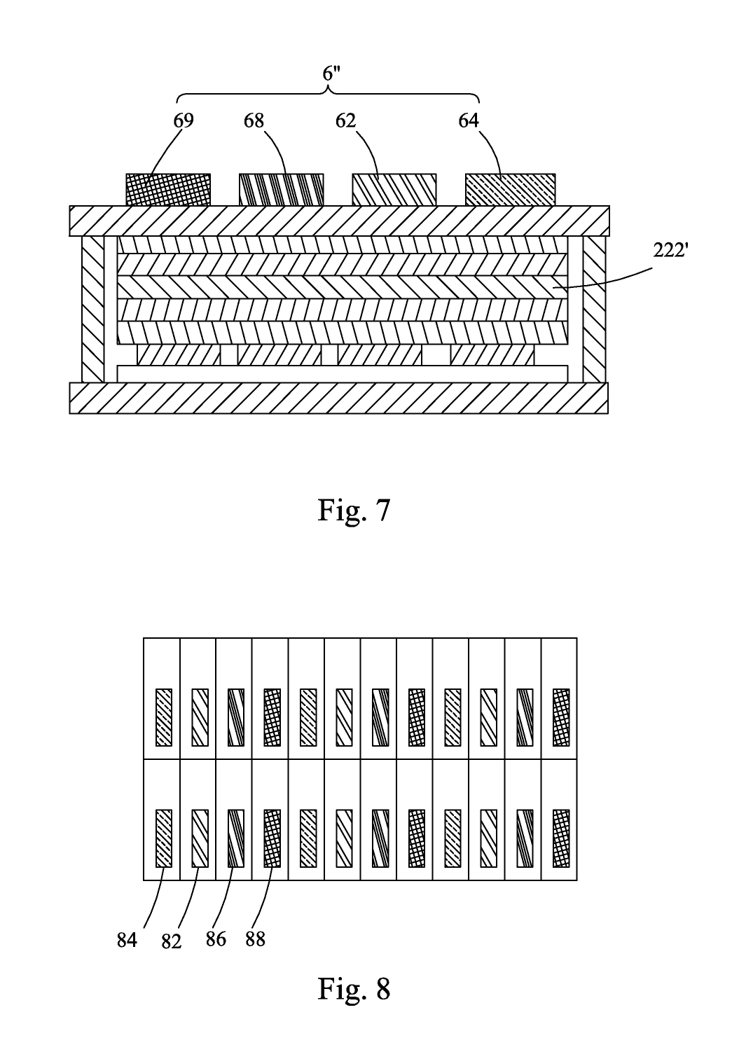

FIG. 7 is a schematic cross-sectional view illustrating a color OLED device according to a third embodiment of the present invention. Please refer to FIG. 7, in this embodiment, the light emitting layer 222″ is a white light emitting layer, the color conversion layer 6″ includes the green quantum dots 62, the red quantum dots 64, the blue quantum dots 68 and white light transmission units 69 disposed in intervals, wherein white light emitting from the light emitting layer 222″ is converted to green light with the green quantum dots 62 in the color conversion layer 6″, white light emitting from the light emitting layer 222″ is converted to red light with the red quantum dots 64 in the color conversion layer 6″, white light emitting from the light emitting layer 222″ is converted to blue light with the blue quantum dots 68 in the color conversion layer 6″, and white light emitting from the light emitting layer 222″ is still the white light with the white light transmission units 69 in the color conversion layer 6″.

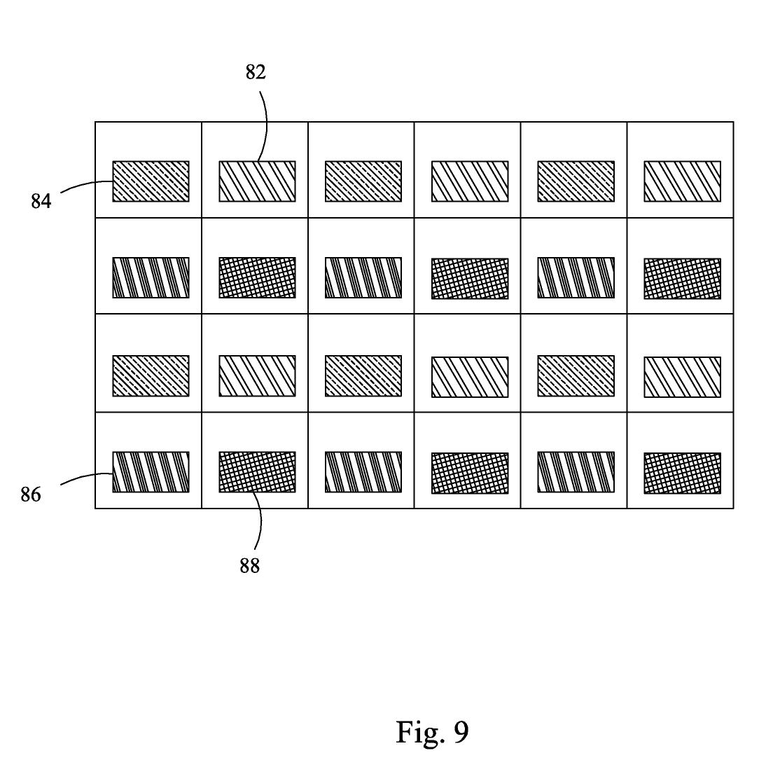

In the third embodiment, each pixel disposed in the color OLED device according to the third embodiment includes four sub-pixels as the red sub-pixel 84, the green sub-pixel 82, the green sub-pixel and a white sub-pixel 88. An arrangement from left to right of the four sub-pixels of each pixel can be either arranged in row as shown in FIG. 8 or in column as shown in FIG. 9. Both the arrangements as shown in FIG. 8 and FIG. 9 can practice the performance of the color OLED device according to the present invention.

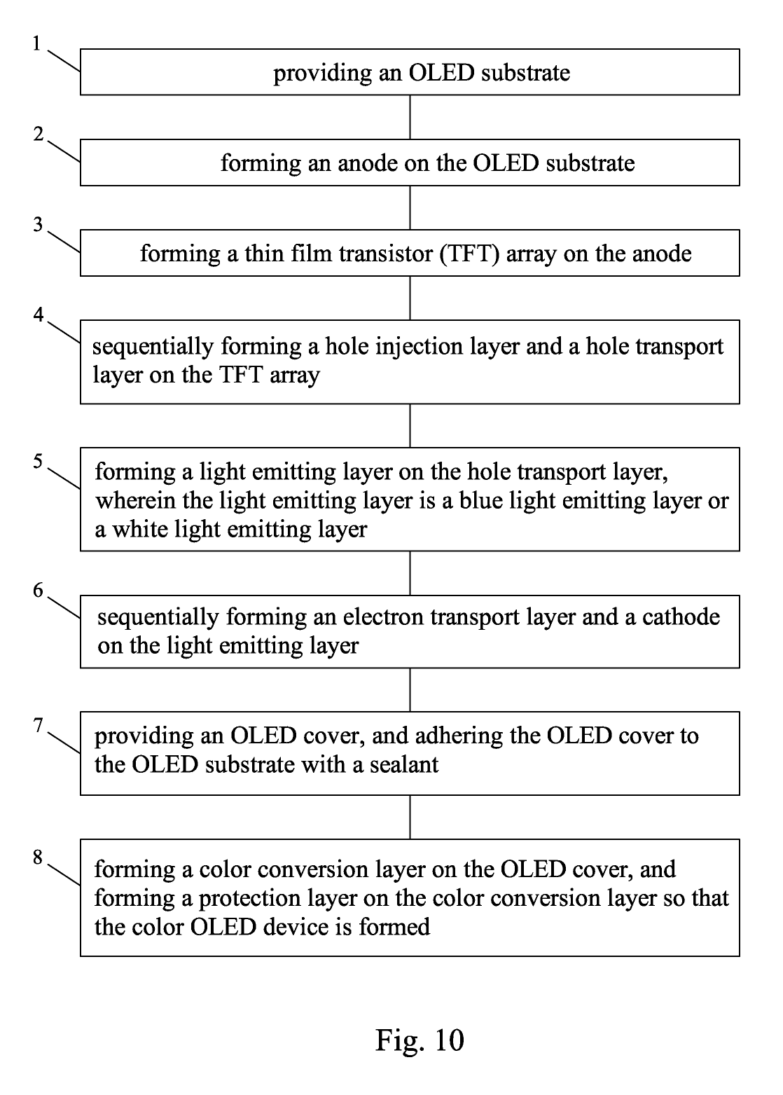

For another aspect, the present invention further provides a method of fabricating a color OLED device. Please refer to FIG. 10 and FIG. 1, the method of fabricating the color OLED device includes steps as follows:

Step 1, providing an OLED substrate 2;

Step 2, forming an anode 224 on the OLED substrate 2;

Step 3, forming a TFT array 225 on the anode 224;

Step 4, sequentially forming a hole injection layer 226 and hole transport layer 227;

Step 5, forming the light emitting layer 222 on the hole transport layer 227, wherein the light emitting layer 222 can be a blue light emitting layer or a white light emitting layer;

Step 6, sequentially forming an electron transport layer 228 and a cathode 229;

Step 7, providing an OLED cover 4, and adhering the OLED cover 4 to the OLED substrate 2 with a sealant; and

Step 8, forming a color conversion layer 6 on the OLED cover 4, so as to form the color OLED device.

In Step 1, the OLED substrate 2 can be fabricated with transparent or flexible material; in a preferred embodiment, the OLED substrate 2 is fabricated with glass substrate.

In Step 2, the anode 224 is formed with Indium tin oxide.

In Step 3, each sub-pixel is corresponding to a thin film transistor (TFT), the TFT controls luminescence and intensity of a region of a light emitting layer corresponding to each sub-pixel.

In Step 4, the hole injection layer 226 is formed by thermal evaporation of polyethylene dioxythiophene (PEDOT), and the hole transport layer 227 is formed by thermal evaporation of poly triphenylamine (poly-TPD).

In Step 5, the light emitting layer 222 can be a blue light emitting layer or a white light emitting layer, in case of the light emitting layer 222 being a blue light emitting layer, the light emitting layer 222 includes blue light emitting material formed by thermal evaporation of polyfluorene, 4,4′-bis(2,2-diphenyl vinyl)biphenyl or bis(2,4-difluorophenyl pyridyl)-tetra(1-pyrazolyl)borate iridium; moreover, the light emitting layer 222 can further include a host blue light material formed by thermal evaporation of 4,4′,4″-tris(carbazol-9-yl)triphenylamine (TCTA), or 2,4,6-(9H-carbazol-9-yl)-1,3,5-triazine (TRZ), the 4,4′,4″-tris(carbazol-9-yl)triphenylamine has a structural formula

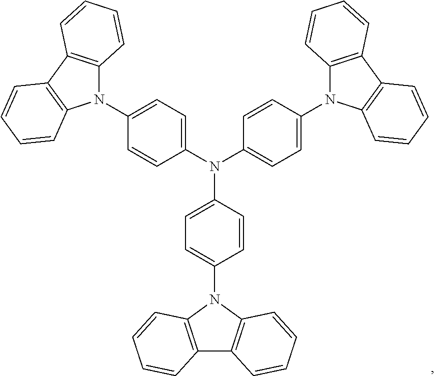 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

as the 2,4,6-(9H-carbazol-9-yl)-1,3,5-triazine has a structural formula as

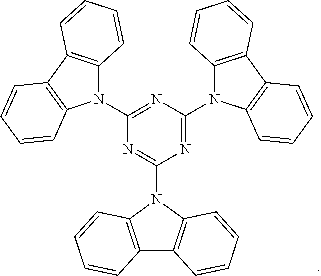 [SMILES: c1ccc2c(c1)c1ccccc1n2-c1nc(-n2c3ccccc3c3ccccc32)nc(-n2c3ccccc3c3ccccc32)n1]

In Step 6, the electron transport layer 228 is formed by thermal evaporation of 8-hydroxyquinoline aluminum (Alq3).

In Step 7, the OLED cover 4 can be fabricated with transparent or flexible material, at least one of the OLED substrate 2 and the OLED cover 4 is fabricated with the transparent material. In an preferred embodiment, both of the OLED substrate 2 and the OLED cover 4 are fabricated with glass substrates, the OLED cover 4 adhered to the OLED substrate 2 can prevent the OLED element 22 from external moisture causing corrosion so as to guarantee lifetime of the color OLED device.

In Step 8, the color conversion layer 6 includes a plurality of quantum dots, light emitting from the light emitting layer 222 is converted to colorized light with the plurality of quantum dots.

Please refer to FIG. 1 and FIG. 2, in case that the light emitting layer 222 is a blue light emitting layer, the color conversion layer 6 includes the green quantum dots 62, the red quantum dots 64 and the blank units 66 disposed in intervals, wherein blue light emitting from the light emitting layer 222 is respectively converted to green light with the green quantum dots 62, red light with the red quantum dots 64 and still the blue light with the blank units 66 in the color conversion layer, so that the blue light emitting from the light emitting layer 222 is converted to colorized light with the plurality of quantum dots.

In this embodiment, each group of the green quantum dot 62, red quantum dot 64 and blank unit 66 is corresponding to a pixel, specifically, each green quantum dot 62 is corresponding to each green sub-pixel 82 of the pixel in the color OLED device, each red quantum dot 64 is corresponding to each red sub-pixel 84 of the pixel therein, and each blank unit 66 is corresponding to the blue sub-pixel 86 of the pixel therein.

In this embodiment, the green quantum dots 62 are formed with cadmium selenide (CdSe), zinc sulfide (ZnS) or zinc selenide doped with copper ions (ZnSe:Cu²⁺); the red quantum dots 64 are formed with cadmium selenide (CdS), cadmium sulfide or zinc sulfide; and the blank units 66 are not identical to the green quantum dots 62 or the red quantum dots which are formed with specific material. A specific way of fabricating the blank units 66 includes steps as follows. Firstly, the red quantum dots 64 corresponding to the red sub-pixels 84 of pixels are formed on the OLED cover 4. Then, the green quantum dots 62 corresponding to the green sub-pixels 82 of pixels are formed on the OLED cover 4. Then, locations above the OLED cover 4 corresponding to blue sub-pixels 86 of pixels are retained, and defined as blank units 66 herein.

Please refer to FIG. 5, the light emitting layer 222′ is a white light emitting layer, the color conversion layer 6′ includes the green quantum dots 62, the red quantum dots 64 and the blue quantum dots 68 disposed in intervals, wherein white light emitting from the light emitting layer 222′ is converted to green light with the green quantum dots 62 in the color conversion layer 6′, white light emitting from the light emitting layer 222′ is converted to red light with the red quantum dots 64 in the color conversion layer 6′, and white light emitting from the light emitting layer 222′ is converted to blue light with the blue quantum dots 68 in the color conversion layer 6′. Please refer to FIG. 6, an arrangement of sub-pixels of pixels disposed in the color OLED device according to the second embodiment of the present invention can be the same as the arrangement of the first embodiment as shown in FIG. 3 or FIG. 4.

Please refer to FIG. 7, the light emitting layer 222″ is a white light emitting layer, the color conversion layer 6″ includes the green quantum dots 62, the red quantum dots 64, the blue quantum dots 68 and white light transmission units 69 disposed in intervals, wherein white light emitting from the light emitting layer 222″ is converted to green light with the green quantum dots 62 in the color conversion layer 6″, white light emitting from the light emitting layer 222″ is converted to red light with the red quantum dots 64 in the color conversion layer 6″, white light emitting from the light emitting layer 222″ is converted to blue light with the blue quantum dots 68 in the color conversion layer 6″, and white light emitting from the light emitting layer 222″ is still the white light with the white light transmission units 69 in the color conversion layer 6″.

Moreover, a protection layer (not shown) can be formed on the color conversion layer 6, and the protection layer as a transparent protection layer can be formed with stearic acid, zinc oxide phosphine, or polymethylmethacrylate. In practice, a solution of stearic acid, zinc oxide phosphine, or polymethylmethacrylate is formed with a solvent; then, the solution thereof is coated over the green quantum dots 62 and the red quantum dots 64; and the protection layer is formed after the solvent has been vaporized. Due to the plurality of quantum dots being nanoparticle, zero-dimensional material, surface-active, and prone to agglomerate resulting in oxidation and fluorescence quenching, the protection can prevent the plurality of quantum dots from resulting in oxidation and fluorescence quenching.

In general, a color OLED device according to the present invention is colorized with the light emitting layer and the plurality of quantum dots, a thickness of the light emitting layer can be shrunken, thus a thickness of the color OLED device can be shrunken; moreover, due to the characteristics of the plurality of quantum dots, such as excellent stability, long lifetime, broader absorption spectral width and color purity, thus a lifetime and color purity of the color OLED device can be enhanced; additionally, a method of fabricating a color OLED device according to the present invention can be fabricated with simplified fabrication processes, so that a fabrication cost of the method thereof can be easily reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A color organic light emitting diode (OLED) device, comprising an OLED substrate, an OLED cover adhered to the OLED substrate and a color conversion layer formed on the OLED cover, wherein the OLED substrate has an OLED element formed thereon, the OLED element comprises a light emitting layer, the color conversion layer comprises a plurality of quantum dots, and light emitting from the light emitting layer is converted to colorized light with the plurality of quantum dots.

2. The color OLED device according to claim 1, wherein the light emitting layer is a blue light emitting layer, the color conversion layer comprises green quantum dots, red quantum dots and blank units disposed in intervals, wherein blue light emitting from the light emitting layer is respectively converted to green light with the green quantum dots, red light with the red quantum dots and still the blue light with the blank units in the color conversion layer.

3. The color OLED device according to claim 2, wherein the light emitting layer comprises a blue light emitting material formed by thermal evaporation of polyfluorene, 4,4′-bis(2,2-diphenyl vinyl)biphenyl or bis(2,4-difluorophenyl pyridyl)-tetra(1-pyrazolyl)borate iridium.

4. The color OLED device according to claim 3, wherein the light emitting layer further comprises a host organic blue light material layer formed by thermal evaporation of 4,4′,4″-tris(carbazol-9-yl)triphenylamine or 2,4,6-(9H-carbazol-9-yl)-1,3,5-triazine.

5. The color OLED device according to claim 2, wherein the green quantum dots are formed with cadmium selenide, zinc sulfide or zinc selenide doped with copper ions; and the red quantum dots are formed with cadmium selenide, cadmium sulfide or zinc sulfide.

6. The color OLED device according to claim 1, wherein the light emitting layer is a white light emitting layer, the color conversion layer comprises green quantum dots, red quantum dots and blue quantum dots disposed in intervals, wherein white light emitting from the light emitting layer is respectively converted to green light with the green quantum dots, red light with the red quantum dots and blue light with the blue quantum dots in the color conversion layer.

7. The color OLED device according to claim 1, wherein the light emitting layer is a white light emitting layer, the color conversion layer comprises green quantum dots, red quantum dots, blue quantum dots and white light transmission units disposed in intervals, wherein white light emitting from the light emitting layer is respectively converted to green light with the green quantum dots, red light with the red quantum dots, blue light with the blue quantum dots and still the white light with the white light transmission units in the color conversion layer.

8. The color OLED device according to claim 1, further comprising a protection layer formed on the color conversion layer, wherein the protection layer is formed with stearic acid, zinc oxide phosphine, or polymethylmethacrylate.

9. The color OLED device according to claim 1, wherein the OLED element comprises an anode formed on the OLED substrate, a thin film transistor (TFT) array formed on the anode, a hole injection layer formed on the TFT array, a hole transport layer formed on the hole injection layer, an electron transport layer formed above the hole transport layer, and a cathode formed on the electron transport layer, wherein the light emitting layer is formed between the hole transport layer and electron transport layer, the hole injection layer is formed with polyethylene dioxythiophene, the hole transport layer is formed with polytriphenylamine, and the electron transport layer is formed with aluminum 8-hydroxyquinoline.

10. A color OLED device, comprising an OLED substrate, an OLED cover adhered to the OLED substrate and a color conversion layer formed on the OLED cover, wherein the OLED substrate has an OLED element formed thereon, the OLED element comprises a light emitting layer, the color conversion layer comprises a plurality of quantum dots, and light emitting from the light emitting layer is converted to colorized light with the plurality of quantum dots;
the light emitting layer is a blue light emitting layer, the color conversion layer comprises green quantum dots, red quantum dots and blank units disposed in intervals, blue light emitting from the light emitting layer is respectively converted to green light with the green quantum dots, red light with the red quantum dots and still the blue light with the blank units in the color conversion layer;
the light emitting layer comprises a blue light emitting material formed by thermal evaporation of polyfluorene, 4,4′-bis(2,2-diphenyl vinyl)biphenyl or bis(2,4-difluorophenyl pyridyl)-tetra(1-pyrazolyl)borate iridium; and
the light emitting layer further comprises a host organic blue light material layer formed by thermal evaporation of 4,4′,4″-tris(carbazol-9-yl)triphenylamine or 2,4,6-(9H-carbazol-9-yl)-1,3,5-triazine.

11. The color OLED device according to claim 10, further comprising a protection layer formed on the color conversion layer, wherein the protection layer is formed with stearic acid, zinc oxide phosphine, or polymethylmethacrylate.

12. The color OLED device according to claim 10, wherein the OLED element comprises an anode formed on the OLED substrate, a thin film transistor (TFT) array formed on the anode, a hole injection layer formed on the TFT array, a hole transport layer formed on the hole injection layer, an electron transport layer formed above the hole transport layer, and a cathode formed on the electron transport layer, wherein the light emitting layer is formed between the hole transport layer and electron transport layer, the hole injection layer is formed with polyethylene dioxythiophene, the hole transport layer is formed with polytriphenylamine, and the electron transport layer is formed with aluminum 8-hydroxyquinoline.

13. The color OLED device according to claim 10, wherein the green quantum dots are formed with cadmium selenide, zinc sulfide or zinc selenide doped with copper ions; and the red quantum dots are formed with cadmium selenide, cadmium sulfide or zinc sulfide.

14. A method of fabricating a color OLED device, comprising steps as follows:
step 1, providing an OLED substrate;
step 2, forming an anode on the OLED substrate;
step 3, forming a thin film transistor (TFT) array on the anode;
step 4, sequentially forming a hole injection layer and a hole transport layer on the TFT array;
step 5, forming a light emitting layer on the hole transport layer, wherein the light emitting layer is a blue light emitting layer or a white light emitting layer;
step 6, sequentially forming an electron transport layer and a cathode on the light emitting layer;
step 7, providing an OLED cover, and adhering the OLED cover to the OLED substrate with a sealant;
step 8, forming a color conversion layer on the OLED cover, and forming a protection layer on the color conversion layer so that the color OLED device is formed, wherein the color conversion layer comprises a plurality of quantum dots, and light emitting from the light emitting layer is converted to colorized light with the plurality of quantum dots;
in case of the light emitting layer being the blue light emitting layer, the color conversion layer comprises green light quantum dots, red light quantum dots and blank units disposed in intervals, wherein blue light emitting from the light emitting layer is respectively converted to green light with the green light quantum dots, red light with the red light quantum dots and still the blue light with the blank units in transmitting the color conversion layer; and
in case of the light emitting layer being the white light emitting layer, the color conversion layer comprises green light quantum dots, red light quantum dots and blue light quantum dots disposed in intervals, wherein white light emitting from the light emitting layer is respectively converted to green light with the green light quantum dots, red light with the red light quantum dots and blue light with the blue light quantum dots in transmitting the color conversion layer.
